(19) United States
(12) Patent Application Publication
(10) Pub. No.: US 2021/0360822 A1
(43) Pub. Date: Nov. 18, 2021

(54) HEAT CONDUCTIVE MEMBER AND ELECTRONIC DEVICE

(71) Applicant: Nidec Chaun-Choung Technology Corporation, New Taipei City (TW)

(72) Inventors: Yu-Po HUANG, Kunshan City Jiangsu (CN); Wang TONY, New Taipei City (TW)

(21) Appl. No.: 17/317,828

(22) Filed: May 11, 2021

(30) Foreign Application Priority Data
May 15, 2020 (CN) 202010411909.1

(51) Int. Cl. H05K 7/20

(52) U.S. Cl. CPC H05K 7/20254; H05K 7/20272; H05K 7/20263

(57) ABSTRACT

A housing includes a first plate and a second plate disposed to face the first plate. In a space of the housing, a groove passing through a heat source contactable portion is formed on at least one of the first plate and the second plate.

### CROSS-REFERENCE TO RELATED APPLICATIONS

The present invention claims priority under 35 U.S.C. § 119 to Chinese Patent Application No. 202010411909.1 filed on May 15, 2020, the entire content of which is incorporated herein by reference.

### FIELD OF THE INVENTION

The present disclosure relates to a heat conductive member and an electronic device.

### BACKGROUND

A conventional vapor chamber is often provided with a container in which a cavity is formed by one plate-like body and another plate-like body facing the one plate-like body, a working fluid enclosed in the cavity, and a wick structure contained in the cavity.

When a vapor chamber receives heat from a heating element, a working fluid in a liquid phase enclosed in the cavity is changed from a liquid phase to a gas phase in a heat receiving part, and the working fluid in the phase-changed gas phase passes through a vapor flow path and moves from the heat receiving part of the vapor chamber to a heat dissipation part. The working fluid in the gas phase that has moved from the heat receiving part to the heat dissipation part dissipates latent heat in the heat dissipation part, and the phase is changed from the gas phase to a liquid phase. The latent heat released in the heat dissipation part is further released to the external environment of the vapor chamber. The working fluid whose phase has been changed from the gas phase to the liquid phase in the heat dissipation part recirculates from the heat dissipation part to the heat receiving part by the capillary force of the wick structure.

In the conventional vapor chamber, for example, the working fluid is held by the wick structure, and the working fluid whose phase has been changed from a gas phase to a liquid phase in the heat dissipation part recirculates from the heat dissipation part to the heat receiving part. That is, the wick structure is provided with a plurality of functions of holding the working fluid and transporting the working fluid from the heat dissipation part to the heat receiving part. Therefore, it may be difficult to sufficiently secure both the function of holding the working fluid and the function of transporting the working fluid from the heat dissipation part to the heat receiving part, in the wick structure.

### SUMMARY

An exemplary heat conductive member of the present disclosure has a heat source contactable portion that is contactable with a heat source, and includes a housing having a space inside, a wick structure disposed in the space, and a working fluid disposed in the space. The housing includes a first plate, and a second plate disposed to face the first plate. In the space, a groove passing through the heat source contactable portion is formed in at least one of the first plate and the second plate.

An exemplary heat conductive member of the present disclosure includes a housing having a space inside, a wick structure disposed in the space, and a working fluid disposed in the space. The housing includes a heating unit that absorbs heat from the outside to the inside of the housing, a cooling unit that is disposed away from the heating unit and cools the heat, and a first plate and a second plate that is disposed facing the first plate. In the space, a groove is provided to at least one of the first plate and the second plate, and the groove extends from the heating unit toward the cooling unit.

An exemplary heat conductive member of the present disclosure includes a housing having a space inside, a wick structure disposed in the space, and a working fluid disposed in the space. The housing includes a first plate and a second plate disposed to face the first plate, and a groove is provided to at least one of the first plate and the second plate.

An exemplary electronic device of the present disclosure includes a heat conductive member.

The above and other elements, features, steps, characteristics and advantages of the present disclosure will become more apparent from the following detailed description of the preferred embodiments with reference to the attached drawings.

### BRIEF DESCRIPTION OF THE DRAWINGS

FIG. 1 is a cross-sectional view of a heat conductive member according to the present disclosure;

FIG. 2 is a plan view schematically showing a heat source contactable portion, a heat source contact portion, and a groove;

FIG. 3 is a plan view schematically showing a heating unit, a cooling unit, and a groove;

FIG. 4 is a plan view according to another embodiment of a heat conductive member;

FIG. 5 is a schematic diagram showing the distance between adjacent pillars and the width of a groove;

FIG. 6 is an enlarged view of part of the groove and the pillar; and

FIG. 7 is a schematic diagram showing an electronic device equipped with the heat conductive member.

### DETAILED DESCRIPTION

Hereinafter, exemplary embodiments of the present disclosure will be described in detail with reference to the drawings. In the present specification, a heat conductive member 100 has a rectangular shape in a plan view, and a first plate 1 and a second plate 2 overlap each other in the gravity direction. It is assumed that the direction in which the first plate 1 and the second plate 2 overlap each other is a Z direction. In the present specification, it is assumed that the direction in which the first plate 1 is disposed is an upper side, and the direction in which the second plate 2 is disposed is a lower side. It is also assumed that when the heat conductive member is viewed from the Z direction, the short direction is an X direction and the longitudinal direction is a Y direction. It should be noted that the above-mentioned designations of the directions are used for explanation, and do not limit the positional relationship and directions of the heat conductive member 100 in the used state.

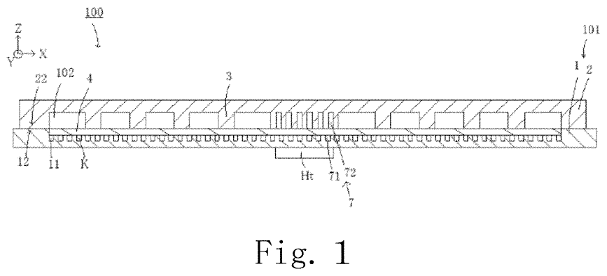

The heat conductive member 100 will be described with reference to FIG. 1. FIG. 1 is a cross-sectional view of the heat conductive member 100 according to the present disclosure cut in the Y direction. The heat conductive member 100 is contactable with a heat source Ht, and contacts the heat source Ht to carry heat from the heat source Ht and lowers the temperature of a heating element Ht. That is, the heat conductive member 100 is used as a heat dissipation member.

The heat conductive member 100 includes a housing 101, a wick structure 4, a working fluid (not shown), and a heat source contactable portion 5.

The housing 101 extends in the longitudinal direction, and has a space 102 inside the housing 101. The wick structure 4 and pillars 3 are disposed inside the space 102. The space 102 is sealed, and a working fluid is sealed in the space 102. That is, the heat conductive member 100 has the housing 101 in which a working fluid is sealed therein.

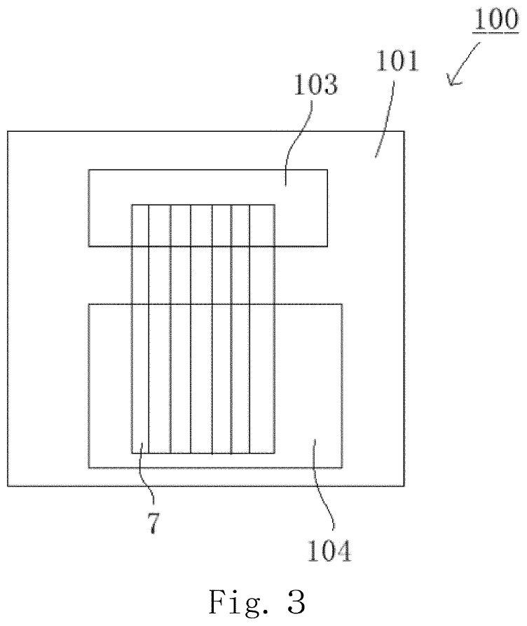

A heating unit 103 and a cooling unit 104 will be described with reference to FIG. 3. FIG. 3 is a plan view schematically showing the heating unit 103, the cooling unit 104, and grooves 7. The heating unit 103 and the cooling unit 104 are regions provided in the housing 101, but are shown by solid lines for convenience. Further, the positions of the heating unit 103 and the cooling unit 104 are examples, and are not limited to those in FIG. 3. The housing 101 has the heating unit 103 and the cooling unit 104. As shown in FIG. 3, one side of the housing 101 in the longitudinal direction (Y direction) is the heating unit 103 that is heated by the heat from the heat source Ht, and the other side is the cooling unit 104. The cooling unit 104 is disposed away from the heating unit 103 to cool the heat from the heat source Ht. The heating element Ht contacts the lower surface of the heating unit 103 in the Z direction. The heat of the heating element Ht is transferred to the cooling unit 104 of the heat conductive member 100. In other words, the heating unit 103 absorbs heat from the outside to the inside of the housing 101. Then, inside the housing 101, the working fluid is heated by the heat from the heating element Ht and evaporates. The evaporated working fluid (not shown) transfers the heat to the housing 101 in the cooling unit 104, is condensed and returned to liquid, and is heated again in the heating unit 103 and evaporates. Through repetition of the above operation, the heat conductive member 100 carries the heat of the heating element Ht and cools the heating element Ht.

In the present embodiment, the cooling unit 104 and the heat source Ht are in direct contact with each other, but may be in indirect contact with each other via, for example, a member that transfers heat of the heat source Ht such as silicone (not shown).

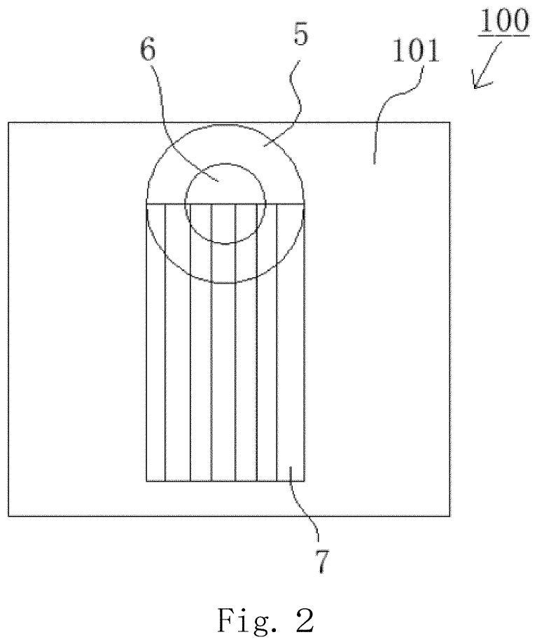

The heat source contactable portion 5 will be described with reference to FIG. 2. FIG. 2 is a plan view schematically showing the heat source contactable portion 5. The heat source contactable portion 5 is a region provided in the housing 101, but is shown by a solid line for convenience. Further, the position of the heat source contactable portion 5 is an example, and is not limited to that shown in FIG. 2. The heat source contactable portion 5 refers to a range where the heat source Ht is contactable in the housing 101. Specifically, the heat source contactable portion 5 refers to a range facing the heat source Ht in the Z direction. The heat source contactable portion 5 can be provided at any position in the housing 101 as long as it can face the heat source Ht.

A heat source contact portion 6 will be described with reference to FIG. 2. FIG. 2 is a plan view schematically showing the heat source contact portion 6. The heat source contact portion 6 is a region provided in the housing 101, but is shown by a solid line for convenience. Further, the position of the heat source contact portion 6 is an example, and is not limited to that shown in FIG. 2. The heat source contactable portion 5 includes the heat source contact portion 6. The heat source contact portion 6 refers to a range that directly or indirectly comes into contact with the heat source Ht. The heat source contact portion 6 can be provided at any position in the housing 101 as long as it is in contact with the heat source Ht. In the present embodiment, the heat source Ht and the heat source contact portion 6 are in direct contact with each other, but may be in indirect contact with each other via, for example, a member that transfers heat such as silicone (not shown).

In the heat conductive member 100 of the present embodiment, water is used as a working fluid (not shown), but the working fluid is not limited to this. For example, alcohol compounds, CFC substitutes, hydrocarbon compounds, fluorinated hydrocarbon compounds, glycol compounds, and the like can be mentioned. As the working fluid, a substance that evaporates (vaporizes) with heat from the heating element Ht in the heating unit 103 and is condensed (liquefied) by transferring the heat to the housing 101 in the cooling unit 104 can be widely adopted.

The heat conductive member 100 will be described in more detail. In the heat conductive member 100, the first plate 1 and the second plate 2 overlap each other in the Z direction, and the outer edges in the X and Y directions are joined. The housing 101 is formed by joining the first plate 1 and the second plate 2. That is, the housing 101 has the first plate 1 and the second plate 2 arranged so as to face the first plate 1.

The first plate 1 is a copper plate. However, the material of the first plate 1 is not limited to copper. As the material of the first plate 1, for example, a metal having a certain strength or more and a certain level of thermal conductivity or more, such as aluminum or an aluminum alloy, can be adopted.

The first plate 1 has a rectangular shape in which the Y direction is the longitudinal direction when viewed from the Z direction. The first plate 1 has a first plate recess 11 and a first plate joint 12. The first plate recess 11 is formed on the upper surface of the first plate 1 in the Z direction, and is recessed downward from the upper surface of the first plate 1 in the Z direction. The first plate recess 11 has a bottom surface portion on the bottom surface. The wick structure 4, which will be described later, is disposed above the bottom surface portion in the Z direction.

In the first plate 1, the first plate joint 12 surrounds the outside of the first plate recess 11. The first plate joint 12 continues along the outer edge of the first plate 1.

A second plate joint 22, described later, of the second plate 2 is joined to the first plate joint 12. The method of joining the first plate joint 12 and the second plate joint 22 will be described later.

As shown in FIG. 1, the first plate 1 has the wick structure 4. That is, the first plate 1 has the wick structure 4 disposed at a position facing the second plate 2. The wick structure 4 is disposed on the first plate 1 and is housed in the space 102 of the housing 101. More specifically, the wick structure 4 is disposed above the bottom surface portion of the first plate recess 11. The working fluid is adsorbed by the wick structure 4. The working fluid adsorbed by the wick structure 4 is transported by the capillarity. By using the wick structure 4, the condensed working fluid can be quickly transported by utilizing the capillarity. As a result, the heat conduction efficiency of the heat conductive member 100 can be improved. Further, the wick structure 4 may be, for example, a porous body such as a wire, a mesh, a non-woven fabric, or a sintered body. The wick structure 4 and the first plate 1 may be formed of a single member.

The second plate 2 is a copper plate. However, it is not limited to this. As the material of the second plate 2, for example, a metal having a certain strength or more and a certain level of thermal conductivity or more, such as aluminum or an aluminum alloy, can be adopted.

The second plate 2 has a rectangular shape in which the Y direction is the longitudinal direction when viewed from the Z direction. The second plate 2 has a second plate recess 21 and the second plate joint 22. The second plate recess 21 is recessed upward in the Z direction from the inner surface of the second plate, and faces the first plate recess 11 in the Z direction. Since the first plate recess 11 and the second plate recess 21 face each other, the space 102 inside the housing 101 can be secured. The second plate joint 22 is formed along the outer edge of the second plate and is joined to the first plate joint 12. As a result, the first plate 1 and the second plate 2 can be joined to seal the space 102 inside the housing. Further, the joining method between the first plate 1 and the second plate 2 can be widely adopted. For example, a method of joining by applying heat and pressure, a method of joining by using an adhesive, and the like may be adoptable.

As shown in FIG. 1, when viewed from the Z direction, the first plate 1 and the second plate 2 have a rectangular shape having the same size or one of which is larger than the other. Here, the outer edge of the first plate 1 and the outer edge of the second plate 2 overlap each other in the Z direction. The first plate 1 may be larger than the second plate 2. In this case, when viewed from the Z direction, the outer edge of the second plate 2 is arranged inside the outer edge of the first plate 1. In the present embodiment, the first plate 1 and the second plate 2 are rectangular when viewed from the Z direction, but the present invention is not limited to this. Other shapes such as a square may be used.

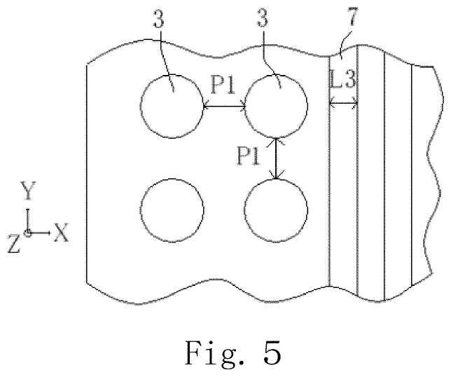

The pillar 3 will be described with reference to FIGS. 1 and 5. FIG. 5 is a plan view showing part of a plurality of pillars 3 and a plurality of grooves 7. The housing 101 has the plurality of pillars 3 extending in the vertical direction to support the first plate 1 and the second plate 2. As shown in FIG. 1, in the heat conductive member 100, the pillar 3 is disposed inside the space 102. Then, as shown in FIG. 5, the plurality of pillars 3 are arranged at equal intervals in the X direction and the Y direction, respectively. That is, the plurality of pillars 3 are arranged at equal intervals in the X direction. Further, the plurality of pillars 3 are arranged at equal intervals in the Y direction as well. In the heat conductive member 100, the arrangement interval in the X direction and the arrangement interval in the Y direction of the plurality of pillars 3 have the same length. Therefore, the arrangement interval in the X direction and the arrangement interval in the Y direction of the plurality of pillars 3 are both set to be an arrangement pitch P1. That is, the plurality of pillars 3 are arranged at equal arrangement intervals. While the interval in the X direction and the interval in the Y direction are assumed to be the same, the intervals are not limited to them and may be different.

The pillar 3 is, for example, in a columnar shape extending in the Z direction. The upper end of the pillar 3 in the Z direction is disposed on the lower surface of the second plate 2 in the Z direction. The lower end of the pillar 3 directly or indirectly contacts the upper surface of the first plate 1. Since the lower end of the pillar 3 directly or indirectly contacts the upper surface of the first plate 1, the plurality of pillars 3 suppress deformation due to a pressure difference between the inside and the outside of the space 102 of the housing 101. Specifically, deformation of the first plate 1 and the second plate 2 can be suppressed. By suppressing the deformation of the first plate 1 and the second plate 2, movement of the working fluid and the evaporated working fluid at the outer edge of the space 102 is less likely to be hindered, and a decrease in the heat conduction efficiency can be suppressed.

In the present embodiment, the lower end portion of the pillar 3 contacts the first plate 1 via the wick structure 4. In other words, the lower end portion of the pillar 3 contacts the upper end of the wick structure 4. Since the lower end portion of the pillar 3 contacts the upper end portion of the wick structure 4, it is possible to prevent the wick structure 4 from floating upward in the Z direction.

In the present embodiment, the pillar 3 is formed of a single member with the second plate 2. As a result, the plurality of pillars 3 can be collectively manufactured by etching for example, and can be easily manufactured. The manufacturing method of the second plate 2 is not limited to etching. A method of forming the pillar 3 as a single member with the first plate 1, by scraping or melting a plate by a chemical or physical method, can be widely adopted. The pillar 3 may be a separate member instead of a single member with the first plate 1.

In the present embodiment, the pillar 3 has a columnar shape. However, it is not limited to have a columnar shape. For example, a cross-sectional shape, cut on a plane orthogonal to the Z direction, may be other than a circle, that is, for example, an ellipse or a polygon. Further, the shape may be tapered upward or downward in the Z direction. Further, the end portion on one side in the Z direction may have a curved surface shape such as a hemispherical shape. Further, it may be a plate-shaped member extending in the X direction or the Y direction. For example, in the case of plate-shaped members extending in the X direction, they may be arranged at equal intervals in the Y direction, and in the case of plate-shaped members extending in the Y direction, they may be arranged at equal intervals in the X direction.

The housing 101 has the groove 7 that opens in the direction where the wick structure 4 is provided. Specifically, in the internal space 102, at least one of the first plate 1 and the second plate 2 has the groove 7. The groove 7 is recessed in the Z direction. The groove 7 may have a cross-sectional shape, cut on a plane orthogonal to the Z direction, other than a circle, that is, for example, an ellipse or a polygon. Further, the shape may be tapered upward or downward in the Z direction. The groove 7 can hold and transport the condensed working fluid.

The housing 101 has, on one side in the longitudinal direction, the heating unit 103 that absorbs heat from the outside to the inside of the housing 101 and, on the other side in the longitudinal direction, the cooling unit 104 that cools the heat. The groove 7 extends in the longitudinal direction and passes through the heating unit 103 and the cooling unit 104. The housing 101 extending in the longitudinal direction has a longer transport distance of the refrigerant, compared with that of the housing 101 in a circular or square shape. Even in the housing 101 extending in the longitudinal direction, refrigerant can be carried from one side to the other.

The first plate 1 and the second plate 2 have the grooves 7. That is, it is desirable that the grooves 7 are provided on both the first plate 1 and the second plate 2. In other words, the housing 101 has a first plate groove 71 and a second plate groove 72, which will be described later. With both the first plate groove 71 and the second plate groove 72 provided to the housing 101, a larger amount of working fluid can be held and the function of recirculating the working fluid can be improved relatively.

For convenience, the groove of the first plate 1 is referred to as the first plate groove 71, and the groove of the second plate 2 is referred to as the second plate groove 72. The positional relationship between the grooves and the wick structure 4 and the positional relationship between the grooves and the pillars 3 will be described later.

The first plate 1 has the first plate groove 71. The first plate groove 71 is recessed downward in the Z direction of the first plate 1. More specifically, the first plate groove 71 is recessed downward in the Z direction from the upper surface of the first plate 1, and opens toward the lower surface of the wick structure 4. As a result, the condensed working fluid can be held in the first plate groove 71, so that a large amount of working fluid to be disposed in the space 102 inside the housing 101 can be secured.

The second plate 2 has the second plate groove 72. The second plate groove 72 is recessed upward in the Z direction of the second plate 2. More specifically, the second plate groove 72 is recessed upward in the Z direction from the lower surface of the second plate 2, and opens toward the upper surface of the wick structure 4. As a result, the condensed working fluid can be held in the second plate groove 72, so that a large amount of working fluid to be disposed in the space 102 inside the housing 101 can be secured.

The groove 7 passes through the heat source contactable portion 5. As a result, the working fluid can be carried to the heat source contactable portion 5. Therefore, with the working fluid being carried to the heat source contactable portion 5, the heat source Ht can be cooled directly or indirectly. The working fluid moves to the heat source contactable portion 5 through not only the wick structure 4 but also the groove 7. That is, it is possible to improve the function of transporting the working fluid to the heat source contactable portion 5, while holding a large amount of working fluid in the groove 7.

Further, it is desirable that the groove 7 passes through the heat source contact portion 6. When the groove 7 passes through the heat source contact portion 6, the working fluid can be carried to the heat source contact portion 6, and the heat source Ht can be directly cooled. The working fluid moves to the heat source contact portion 6 through not only the wick structure 4 but also the groove 7. That is, it is possible to improve the function of transporting the working fluid to the heat source contact portion 6, while holding a large amount of working fluid in the groove 7. Further, since the groove 7 extends in the direction away from the heat source contact portion 6, it is possible to secure a large amount of working fluid held in the groove 7, and to further improve the function of transporting the working fluid to the heat source contact portion 6.

In the present embodiment, the groove 7 extends from the heating unit 103 toward the cooling unit 104. Specifically, the groove 7 passes through the heating unit 103 and the cooling unit 104. The liquid working fluid condensed by the cooling unit 104 can be carried to the heating unit 103 that absorbs heat generated from the heat source Ht. Specifically, the vapor of the evaporated working fluid is condensed by the cooling unit 104 and returned to a liquid working fluid. The liquid working fluid is carried from the cooling unit 104 to the heating unit 103 through not only the wick structure 4 but also the groove 7. As a result, the function of transporting the working fluid from the cooling unit 104 to the heating unit 103 can be improved.

In the cooling unit 104, it is desirable that the groove 7 is disposed at a hottest portion of the heat source Ht, but is not limited to this. Further, it is desirable that the groove 7 continues from the heating unit 103 to the cooling unit 104 without interruption. When the groove 7 continues, it is possible to prevent the working fluid transported from the cooling unit 104 to the heating unit 103 from flowing from an interrupted portion of the groove 7 to a portion other than the heating unit 103.

Next, the positional relationship between the groove and the wick structure 4 will be described. For convenience, the positional relationship will be described using the first plate groove 71 and the wick structure 4.

The first plate groove 71 has a first edge portion 711 and a first groove bottom portion 712. The first edge portion 711 is arranged at the end of the opening that opens toward the lower surface of the wick structure 4. The first groove bottom portion 712 is a bottom surface of the first plate groove 71, and is located below the first edge portion 711 in the Z direction. In the present embodiment, the first groove bottom portion 712 overlaps the opening when viewed from the Z direction. More specifically, the first plate groove 71 extends parallel to the Z direction from the first edge portion 711 toward the first groove bottom portion 712.

The first edge portion 711 of the first plate groove 71 and the wick structure 4 contact each other, and the first groove bottom portion 712 of the first plate groove 71 and the lower surface of the wick structure 4 in the Z direction face each other with a gap. As a result, a groove space K can be formed by the first plate groove 71 and the wick structure 4. In other words, the lower surface of the wick structure 4 covers the opening of the first plate groove 71. That is, the groove space K is a space formed by being surrounded by the first groove bottom portion 712, the inner side surfaces of the first groove 71, and the wick structure 4.

The groove space K can hold and transport the working fluid. Since the opening of the first plate groove 71 is covered with the lower surface of the wick structure 4, the groove space K can allow the working fluid to move efficiently without the working fluid leaking upward in the Z direction. Further, it is desirable that the first edge portion 711 of the first plate groove 71 and the wick structure 4 contact each other, but may not contact each other. It suffices if the distance between the first edge portion 711 of the first plate groove 71 and the wick structure 4 is short. For example, it suffices if the gap between the first edge portion 711 of the first plate groove 71 and the wick structure 4 is narrower than the gap between the lower end portion of the pillar 3 in the Z direction and the upper surface of the wick structure 4. When the first edge portion 711 of the first plate groove 71 contacts the wick structure 4, the working fluid transport function of the wick structure 4 may be affected. Therefore, by preventing the first edge portion 711 of the first plate groove 71 from coming into contact with the wick structure 4, it is possible to secure the groove space K to be wide while suppressing the influence on the transport function for the working fluid of the wick structure 4.

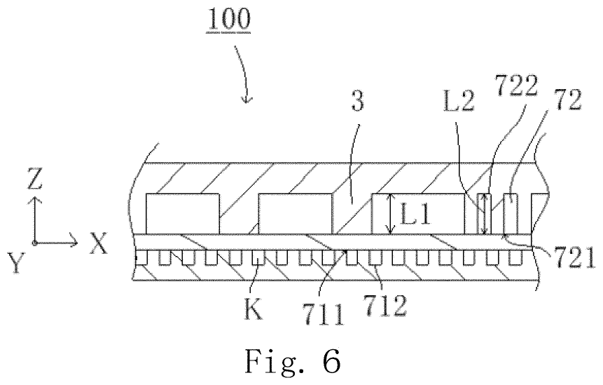

Next, the relationship between the groove 7 and the pillar 3 will be described with reference to FIGS. 5 and 6. FIG. 6 is an enlarged view of the second groove 72 and the pillar 3 cut in the X direction in which the dotted line portion of FIG. 1 is enlarged. For convenience, the positional relationship between the groove and the pillar will be described using the second plate groove 72 and the pillar 3.

A width L3 of the second plate groove 72 in the short direction (width in the X direction) is smaller than the shortest distance between the adjacent pillars 3. The width of the second plate groove 72 in the short direction refers to the narrowest portion in the short direction of the second plate groove 72. That is, the width of the second plate groove 72 in the short direction is narrower than an arrangement pitch P1. By doing so, the width of the second plate groove 72 in the short direction can be narrowed, so that the working fluid in the second plate groove 72 is sandwiched between the side surfaces of the second plate groove 72 and remains in the second plate groove 72. Therefore, it is possible to prevent the working fluid held in the second plate groove 72 from leaking to the outside of the second plate groove 72.

The second plate groove 72 has a second edge portion 721 and a second groove bottom portion 722. The second edge portion 721 is arranged at the end of the opening that opens toward the top surface of the wick structure 4. The second groove bottom portion 722 is an upper surface of the second plate groove 72, and is located above the second edge portion 721 in the Z direction. In the present embodiment, the second groove bottom portion 722 overlaps the opening of the second plate groove 72 when viewed from the Z direction. More specifically, the second plate groove 72 extends parallel to the Z direction from the second edge portion 721 toward the second groove bottom portion 722.

As shown in FIG. 6, in the internal space 102, the length from the lower surface of the second plate 2 to the lower end of the pillar 3 in the Z direction is defined as L1. L1 refers to the shortest distance from the lower surface of the second plate 2 to the lower end of the pillar 3 in the Z direction. L1 refers to the so-called length of the pillar 3 in the Z direction. Further, the length in the Z direction from the second edge portion 721 to the second groove bottom portion 722 of the second plate groove 72 is defined as L2. L2 refers to the shortest distance between the second edge portion 721 of the second plate groove 72 and the second plate groove 72. L2 refers to the so-called depth of the second plate groove 72.

In the present embodiment, L2 is smaller than L1. That is, in the direction in which the first plate 1 and the second plate 2 are arranged (Z direction), the depth of the second plate groove 72 is smaller than the length of the pillar 3. By making the depth of the second plate groove 72 shorter than the pillar 3, it is possible to suppress reduction of the volume of the second plate 2. Therefore, the heat capacity of the second plate 2 can be secured.

Meanwhile, L2 and L1 may be equal, or L2 may be larger than L1. That is, in the direction in which the first plate 1 and the second plate 2 are arranged (Z direction), the depth of the second plate groove 72 is the same as or larger than the length of the pillar 3. By making the depth of the second plate groove 72 the same as or larger than the length of the pillar 3, a large amount of working fluid can be secured in the second plate groove 72.

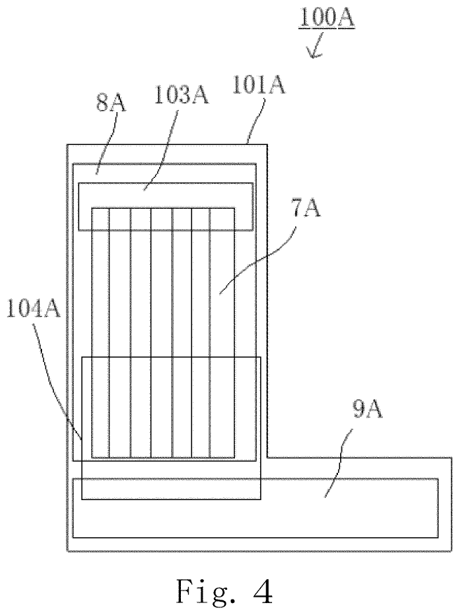

FIG. 4 is a plan view of a heat conductive member 100A according to another embodiment of the present disclosure. A first region 8A and a second region 9A, which will be described later, are regions provided in the housing, but are indicated by solid lines for convenience, and grooves are indicated by dotted lines. For convenience of explanation, the same parts as those of the above-described embodiment of the present disclosure are denoted by the same reference numerals.

A housing 101A has, on one side in the longitudinal direction, a heating unit 103A that absorbs heat from the outside to the inside of the housing 101A and, on the other side in the longitudinal direction, a cooling unit 104A that cools the heat. A groove 7A extends in the longitudinal direction and passes through the heating unit 103A and the cooling unit 104A. The housing 101A extending in the longitudinal direction has a longer transport distance of the refrigerant, compared with a housing in a circular or square shape. Even in the housing extending in the longitudinal direction, refrigerant can be carried from one side to the other.

The housing 101A has the first region 8A extending from one side to the other side in the longitudinal direction. The first region 8A refers to a region from an end on one side to an end of the other side of the housing 101A in the longitudinal direction. The housing 101A has the second region 9A extending from the other side of the first region 8A in the longitudinal direction in a direction intersecting the longitudinal direction. The first region 8A faces the heat source in the Z direction. In other words, the first region 8A has the heating unit 103A. The second region 9A extends from the end on the other side in the longitudinal direction in a direction intersecting the longitudinal direction, and has the cooling unit 104A. In the other embodiment, the groove 7A passes through at least the first region 8A of the first region 8A and the second region 9A. As a result, the working fluid can be transported even in the heat conductive member 101A extending in the longitudinal direction and the direction intersecting the longitudinal direction.

As shown in FIG. 4, in the present other embodiment, the first region 8A and the second region 9A intersect in orthogonal directions, but they are not limited thereto.

As described above, it is desirable that a plurality of grooves 7 are provided and they continue without interruption. In the arrangement direction of the grooves 7, the surfaces connecting the edges of the adjacent grooves 7 may directly or indirectly contact at least one of the first plate 1 and the second plate 2 in the Z direction. By directly or indirectly contacting at least one of the first plate 1 and the second plate 2, the surface connecting the edges of the adjacent grooves 7 suppress deformation due to a pressure difference between the inside and outside of the space 102 of the housing 101. Specifically, deformation of the first plate 1 and the second plate 2 can be further suppressed. It suffices that the surfaces connecting the edges of the adjacent grooves 7 contact at least one of the first plate 1 and the second plate 2 via the wick structure 4 in the Z direction.

The heat conductive member of the present disclosure is a so-called vapor chamber that carries heat of the heating element Ht by utilizing a state change of the working fluid enclosed in the space 102, that is, utilizing evaporation by heating and condensation by cooling.

Examples of the heating element Ht include, but are not limited to, devices having integrated circuits such as a CPU, an MPU, and a memory, a hard disk, and a rotary body such as an optical disk. The heat conductive member can be widely used for heat dissipation of a device that generates heat during operation.

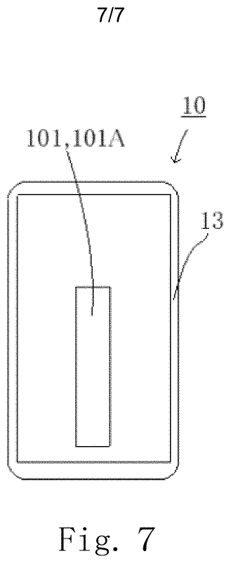

FIG. 7 is a plan view of an electronic device 10 which is an example of using the heat conductive member 101 or 101A of the present disclosure. The heat conductive member 101 or 101A is shown by a solid line for convenience. The shape and position of the heat conductive member 101 or 101A are examples.

The electronic device 10 has a case 13. The case 13 has, for example, a space inside. The case 13 has the heat conductive member 100 or 100A. Specifically, the heat conductive member 100 or 100A is arranged inside the case 13. Therefore, it is possible to provide the electronic device 10 provided with the heat conductive member 100 or 100A in which the function of holding the working fluid and recirculating the working fluid is relatively improved. The electronic device 10 includes, but is not limited to, a device such as a smartphone, a tablet PC, or a personal computer.

In the present disclosure, the heat conductive member 100 or 100A may be used so that the Y direction and the gravity direction coincide with each other. For example, when the heat source contactable portion 5 is disposed so as to be at an upper side in the gravity direction, the working fluid tends to move downward in the gravity direction according to the gravity, so that the capillarity of the wick structure 4 is reduced and the function of transporting the refrigerant upward in the gravity direction is reduced. By providing the groove 7, even if the function of the wick structure 4 deteriorates, it is possible to transport the refrigerant to the heat source contactable portion 5 by the groove 7. That is, even if the heat source contactable portion 5 is disposed so as to face upward in the gravity direction, it is possible to suppress deterioration in the performance of the heat conductive member 100 or 100A. While description has been given above by using the heat source contactable portion 5 as an example, the same effect can be achieved even in the case where the heating unit 103 is arranged at the upper side in the gravity direction and the cooling unit 104 is arranged at the lower side in the gravity direction. Further, it is effective not only when the Y direction and the gravity direction completely match, but also when, for example, the heating unit 103 is provided above the cooling unit 104 in the gravity direction.

Although the embodiments of the present disclosure have been described above, the present disclosure is not limited to this content. Further, various modifications can be made to the embodiments of the present disclosure as long as they do not deviate from the purpose of the disclosure.

Features of the above-described preferred embodiments and the modifications thereof may be combined appropriately as long as no conflict arises.

While preferred embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. A heat conductive member having a heat source contactable portion that is contactable with a heat source, the heat conductive member comprising:
a housing having a space inside;
a wick structure disposed in the space; and
a working fluid disposed in the space,
wherein the housing includes
a first plate and a second plate disposed to face the first plate, and
in the space, a groove passing through the heat source contactable portion is formed in at least one of the first plate and the second plate.

2. The heat conductive member according to claim 1, wherein
the heat source contactable portion includes a heat source contact portion that comes into contact with the heat source, and
the groove passes through the heat source contact portion.

3. The heat conductive member according to claim 1, wherein
the groove extends in a direction away from the heat source contact portion.

4. A heat conductive member comprising:
a housing having a space inside;
a wick structure disposed in the space; and
a working fluid disposed in the space,
wherein the housing includes:
a heating unit that absorbs heat from an outside to an inside of the housing;
a cooling unit that is disposed away from the heating unit and cools the heat; and
a first plate and a second plate disposed to face the first plate,
in the space, a groove is provided to at least one of the first plate and the second plate, and
the groove extends from the heating unit toward the cooling unit.

5. The heat conductive member according to claim 4, wherein the groove passes through the heating unit and the cooling unit.

6. A heat conductive member comprising:
a housing having a space inside;
a wick structure disposed in the space; and
a working fluid disposed in the space,
wherein the housing includes
a first plate and a second plate disposed to face the first plate, and
a groove is provided to at least one of the first plate and the second plate.

7. The heat conductive member according to claim 6, wherein
the housing extends in a longitudinal direction, and
the groove extends in the longitudinal direction.

8. The heat conductive member according to claim 6, wherein
the housing includes:
on one side in a longitudinal direction, a heating unit that absorbs heat from an outside to an inside of the housing; and
on another side in the longitudinal direction, a cooling unit that cools the heat, and
the groove passes through the heating unit.

9. The heat conductive member according to claim 8, wherein the groove passes through the cooling unit.

10. The heat conductive member according to claim 9, wherein the housing includes:
a first region extending from one side to another side in the longitudinal direction; and
a second region extending from the other side in the longitudinal direction of the first region in a direction intersecting the longitudinal direction,
the first region includes the heating unit,
the second region includes the cooling unit, and
the groove passes through at least the first region of the first region and the second region.

11. The heat conductive member according to claim 10, wherein the groove extends continuously.

12. The heat conductive member according to claim 11, wherein
a plurality of the grooves are provided, and
the plurality of grooves are arranged parallel to each other.

13. The heat conductive member according to claim 12, wherein
an edge of the groove and the wick structure contact each other, and
a bottom portion of the groove and the wick structure face each other with a gap.

14. The heat conductive member according to claim 13, further comprising in an internal space, a pillar that is disposed on at least one of the first plate and the second plate and extends toward another one of the first plate and the second plate,
wherein a plurality of the pillars are provided, and
a width of the groove in a short direction is smaller than a shortest distance between adjacent pillars.

15. The heat conductive member according to claim 14, wherein in a direction in which the first plate and the second plate are disposed, a depth of the groove is smaller than a length of the pillar.

16. The heat conductive member according to claim 14, wherein in a direction in which the first plate and the second plate are disposed, a depth of the groove is same as or larger than a length of the pillar.

17. The heat conductive member according to claim 16, wherein each of the first plate and the second plate has the groove.

18. An electronic device comprising the heat conductive member according to claim 1.
